(19) United States
(12) Patent Application Publication
(10) Pub. No.: US 2018/0171172 A1
(43) Pub. Date: Jun. 21, 2018

(54) RESIN COMPOSITION FOR FORMING PHASE-SEPARATED STRUCTURE AND METHOD OF PRODUCING STRUCTURE INCLUDING PHASE-SEPARATED STRUCTURE

(71) Applicant: TOKYO OHKA KOGYO CO., LTD., Kawasaki-shi (JP)

(72) Inventors: Hitoshi YAMANO, Kawasaki-shi (JP); Takahiro DAZAI, Kawasaki-shi (JP); Tasuku MATSUMIYA, Kawasaki-shi (JP)

(21) Appl. No.: 15/843,387

(22) Filed: Dec. 15, 2017

(30) Foreign Application Priority Data
Dec. 21, 2016 (JP) 2016-248488

(51) Int. Cl. C09D 153/00; C09D 5/00; C09D 7/20; C08J 3/28; G03F 7/16; G03F 7/20; G03F 7/26

(52) U.S. Cl. CPC C09D 153/00; C09D 5/00; C09D 7/20; C08J 2353/00; G03F 7/16; G03F 7/2006; G03F 7/26; C08J 3/28

(57) ABSTRACT

A resin composition for forming a phase-separated structure includes a block copolymer in which a hydrophilic block and a hydrophobic block are bonded to each other, and a solvent component (S) containing an organic solvent (S1) having a boiling point of 200° C. or higher.

### BACKGROUND OF THE INVENTION

### Field of the Invention

The present invention relates to a resin composition for forming a phase-separated structure, and a method of producing a structure including a phase-separated structure.

This application claims priority to Japanese Patent Application No. 2016-248488, filed Dec. 21, 2016, the entire content of which is incorporated herein by reference.

### Description of Related Art

In recent years, in accordance with further miniaturization of a large scale integrated circuit (LSI), a technique for processing a more delicate structure has been demanded.

In response to such a demand, a technique for forming a finer pattern using a phase-separated structure formed by self-organization of a block copolymer in which incompatible blocks are bonded to each other has been developed (for example, refer to Japanese Unexamined Patent Application, First Publication No. 2008-36491).

In order to utilize the phase-separated structure of the block copolymer, it is essential to form self-organization nanostructures formed by micro phase separation only in a specific area, and arrange the self-organization nanostructures in a desired direction. In order to realize position control and orientation control of the self-organization nanostructures, a processes such as graphoepitaxy for controlling a phase-separated pattern by a guide pattern and chemical epitaxy for controlling a phase-separated pattern by difference in a chemical state of substrates have been proposed (for example, refer to Proceedings of SPIE, Vol. 7637, 76370 G-1 to 11 (2010)).

The block copolymer forms a structure having a regular periodic structure by phase separation.

The “period of a structure” means a period of the phase structure observed when the structure including the phase-separated structure is formed, and refers to a sum of lengths of the respective phases incompatible with each other. In a case where the phase-separated structure forms a cylinder structure perpendicular to the substrate surface, the period (L0) of the structure corresponds to a distance (pitch) between centers of two adjacent cylinder structures.

The period (L0) of the structure has been known to be determined by the intrinsic polymerization properties such as a degree of polymerization N, and an interaction parameter χ of Flory-Huggins. That is, the larger a product “χ·N” of χ and N, the larger mutual repulsion between different blocks in the block copolymer. For this reason, when a relationship of χ·N>10 (hereinafter referred to as “intensity separation limit point”) is established, it is more likely that the repulsion between different types of blocks in the block copolymer is large, and the phase separation occurs. In addition, in the intensity separation limit point, the period of the structure is approximately N^{2/3}·χ^{1/6}, and the relationship of Expression (1) is established. That is, the period of the structure is proportional to the degree of polymerization N correlated with the molecular weight and the molecular weight ratio between different blocks.

L0∝ a·N^{2/3}·χ^{1/6} (1)

[In Expression, L0 represents a period of the structure. a represents a parameter indicating the size of the monomer. N represents a degree of polymerization. χ represents an interaction parameter, in which the larger this value, the higher the phase-separation performance.]

Accordingly, it is possible to adjust the period (L0) of the structure by adjusting the composition of the block copolymer and a total molecular weight.

It is known that the periodic structure which the block copolymer forms varies the form such as a cylinder (columnar phase), a lamella (plate phase), and a sphere (spherical phase) depending on the volume ratio of the polymer components, and the period depends on the molecular weight.

Therefore, a method for increasing the molecular weight of the block copolymers can be considered in order to form the structure of a relatively large period (L0) by utilizing the phase-separated structure formed by the self-organization of the block copolymers.

### SUMMARY OF THE INVENTION

In producing a structure including a phase-separated structure using a block copolymer composition, there is still room for improvement in order to more satisfactorily form a phase-separated structure.

The present invention has been made in view of the above circumstances, and an object of the present invention is to provide a resin composition for forming a phase-separated structure, which is capable of satisfactorily forming a phase-separated structure, and a method of producing a structure including a phase-separated structure using the aforementioned resin composition.

In order to achieve the above object, the present invention adopts the following configuration.

That is, a first aspect of the present invention is to provide a resin composition for forming a phase-separated structure including a block copolymer in which a hydrophilic block and a hydrophobic block are bonded to each other, and a solvent component (S) containing an organic solvent (S1) having a boiling point of 200° C. or higher.

A second aspect of the present invention is to provide a method of producing a structure including a phase-separated structure, the method including apllying the resin composition for forming a phase-separated structure of the first aspect to a support to form a layer including the block copolymer, and phase-separating the layer including the block copolymer.

According to the present invention, it is possible to provide a resin composition for forming a phase-separated structure, which is capable of satisfactorily forming a phase-separated structure, and a method of producing a structure including a phase-separated structure using the aforementioned resin composition.

### BRIEF DESCRIPTION OF THE DRAWINGS

FIG. 1 is a schematic process diagram illustrating an exemplary embodiment of a method of producing a structure including a phase-separated structure according to the present invention.

FIG. 2 is a diagram illustrating an exemplary embodiment of an optional step.

FIG. 3 is a schematic process diagram illustrating an exemplary embodiment of a method of producing a structure including a phase-separated structure according to the present invention.

FIG. 4 is a diagram illustrating an exemplary embodiment of an optional step.

### DETAILED DESCRIPTION OF THE INVENTION

In the specification and claims of the present application, “aliphatic” is a relative concept with respect to aromatic, and is defined as a group, a compound, or the like having no aromaticity.

“Alkyl group” is assumed to contain a linear, branched, or cyclic monovalent saturated hydrocarbon group unless otherwise noted. The same is true for an alkyl group in an alkoxy group.

“Alkylene group” is assumed to contain a linear, branched, and cyclic divalent saturated hydrocarbon group unless otherwise noted.

“Halogenated alkyl group” is a group obtained by substituting a portion or all of the hydrogen atoms in an alkyl group with halogen atoms, and examples of the halogen atom include a fluorine atom, a chlorine atom, a bromine atom, and an iodine atom.

“Fluorinated alkyl group” or “fluorinated alkylene group” means a group obtained by substituting a portion or all of the hydrogen atoms in an alkyl group or an alkylene group with a fluorine atom.

“Constituting unit” means a monomer unit constituting a polymer compound (a resin, a polymer, or a copolymer).

The phrase “may have a substituent” means both a case of substituting a hydrogen atom (—H) with a monovalent group and a case of substituting a methylene group (—CH₂—) with a divalent group.

“Exposure” is a concept including radiation irradiation in general.

“Constituting unit derived from acrylic ester” means a constituting unit formed by cleavage of an ethylenic double bond of the acrylic ester.

“Acrylic ester” is a compound obtained by substituting a hydrogen atom at a carboxy group terminal of an acrylic acid (CH₂═CH—COOH) with an organic group.

The acrylic ester may be obtained by substituting a hydrogen atom bonded to an α-position carbon atom with a substituent. The substituent (R^{α0}) with which the hydrogen atom bonded to the α-position carbon atom is substituted is an atom other than the hydrogen atom or a group, and examples thereof include an alkyl group having 1 to 5 carbon atoms and a halogenated alkyl group having 1 to 5 carbon atoms. In addition, it is assumed that the acrylic ester includes itaconic diester obtained by substituting the substituent (R^{α0}) with a substituent containing an ester bond, and α-hydroxyacrylic ester obtained by substituting the substituent (R^{α0}) with a group modified with a hydroxyalkyl group or a hydroxyl group thereof. Note that, the α-position carbon atoms in the acrylic ester is a carbon atom to which a carbonyl group of an acrylic acid is bonded unless otherwise noted.

Hereinafter, acrylic ester obtained by substituting the hydrogen atom bonded to a α-position carbon atom with a substituent may be referred to as α-substituted acrylic ester. In addition, both of the acrylic ester and the α-substituted acrylic ester may be referred to as “(α-substituted) acrylic ester”.

“Constituting unit derived from hydroxystyrene” means a constituting unit formed by cleavage of an ethylenic double bond of hydroxystyrene. “Constituting unit derived from a hydroxystyrene derivative” means a constituting unit formed by cleavage of an ethylenic double bond of a hydroxystyrene derivative.

“Hydroxystyrene derivative” includes those obtained by substituting an α-position hydrogen atom of hydroxystyrene with other substituents such as an alkyl group and a halogenated alkyl group, and derivatives thereof. Examples of the derivatives include a derivative obtained by substituting a hydrogen atom of a hydroxyl group of hydroxystyrene in which the α-position hydrogen atom may be substituted with a substituent with an organic group; and a derivative in which a substituent other than the hydroxyl group is bonded to a benzene ring of hydroxystyrene in which α-position hydrogen atom may be substituted with a substituent. Here, the α-position (α-position carbon atom) means a carbon atom to which a benzene ring is bonded unless otherwise noted.

As the substituent with which the α-position hydrogen atoms in the hydroxystyrene are substituted, the same substituent as that exemplified as a α-position substituent in the α-substituted acrylic ester can be used.

“Styrene” is a concept including styrene and those obtained by substituting an α-position hydrogen atoms in the styrene with other substituents other than an alkyl group and a halogenated alkyl group.

“Styrene derivative” is a concept including those obtained by substituting the α-position hydrogen atoms in the styrene with other substituents such as an alkyl group and a halogenated alkyl group, and the derivatives thereof. Examples of the derivatives include a derivative in which a substituent is bonded to a benzene ring of hydroxystyrene in which the α-position hydrogen atom may be substituted with a substituent. Here, the α-position (α-position carbon atom) means a carbon atom to which a benzene ring is bonded unless otherwise noted.

“Constituting unit derived from the styrene” and “constituting unit derived from the styrene derivative” mean constituting units formed by cleavage of an ethylenic double bond of the styrene or the styrene derivative.

The alkyl group as the α-position substituent is preferably a linear or branched alkyl group, and specifically, examples thereof include an alkyl group having 1 to 5 carbon atoms (a methyl group, an ethyl group, a propyl group, an isopropyl group, an n-butyl group, an isobutyl group, a tert-butyl group, a pentyl group, an isopentyl group, and a neopentyl group).

In addition, specific examples of the halogenated alkyl group as the α-position substituent include a group obtained by substituting a portion or all of the hydrogen atoms in “the alkyl group as the α-position substituent” with a halogen atom. Examples of the halogen atom include a fluorine atom, a chlorine atom, a bromine atom, and an iodine atom, and particularly, a fluorine atom is preferable.

Further, specific examples of the hydroxyalkyl group as the α-position substituent include a group obtained by substituting a portion or all of the hydrogen atoms in the “alkyl group as the α-position substituent” with a hydroxyl group. The number of the hydroxyl groups in the hydroxyalkyl group is preferably of 1 to 5, and is most preferably 1.

(Resin Composition for Forming Phase-Separated Structure)

According to the first aspect of the present invention, a resin composition for forming a phase-separated structure includes a block copolymer in which a hydrophilic block and a hydrophobic block are bonded to each other, and a solvent component (S) containing an organic solvent (S1) having a boiling point of 200° C. or higher.

<Block Copolymer>

The block copolymer is a polymer in which a plurality of kinds of blocks are bonded to each other (a partial constituting component in which the same kinds of constituting units are repeatedly bonded). The blocks constituting the block copolymer may be of two kinds, or of three or more kinds.

The block copolymer in the embodiment is a block copolymer in which a hydrophilic block and a hydrophobic block are bonded to each other.

A hydrophilic block is a block having a relatively high affinity with water as compared with other blocks among a plurality of blocks constituting a block copolymer. A polymer (p1) constituting the hydrophilic block is composed of a constituting unit having relatively high affinity with water as compared with a polymer (p2) constituting the other block.

The hydrophobic block is a block other than the hydrophilic block among the plurality of blocks constituting the block copolymer. The polymer (p2) constituting the hydrophobic block is composed of a constituting unit having a relatively low affinity with water as compared with the polymer (p1).

The plurality of blocks constituting the block copolymer are not particularly limited as long as it is a combination that occurs the phase separation, and are preferably a combination of blocks incompatible with each other. Further, as the blocks, it is preferable to use a combination in which a phase formed of at least one kind of block among the plurality of kinds of blocks constituting the block copolymer can be easily and selectively removed as compared with phases formed of other kinds of blocks. As the combination which can be easily and selectively removed, a block copolymer in which one or two or more kinds of blocks having an etching selectivity ratio of larger than 1 are bonded is exemplified.

Examples of the block copolymer include a block copolymer in which a block of a constituting unit having an aromatic group and a block of a constituting unit derived from (α-substituted) acrylic ester are bonded to each other; a block copolymer in which the block of the constituting unit having an aromatic group and a block of a constituting unit derived from (α-substituted) acrylic acid are bonded to each other; a block copolymer in which the block of the constituting unit having an aromatic group and a block of a constituting unit derived from siloxane or its derivatives are bonded to each other; a block copolymer in which a block of a constituting unit derived from alkylene oxide and the block of the constituting unit derived from (α-substituted) acrylic ester are bonded to each other; a block copolymer in which the block of the constituting unit derived from alkylene oxide and the block of a constituting unit derived from (α-substituted) acrylic acid are bonded to each other; a block copolymer in which a block of a constituting unit containing a silsesquioxane structure and the block of the constituting unit derived from (α-substituted) acrylic ester are bonded to each other; a block copolymer in which the block of the constituting unit containing a silsesquioxane structure and the block of a constituting unit derived from (α-substituted) acrylic acid are bonded to each other; and a block copolymer in which the block of the constituting unit containing a silsesquioxane structure and the block of the constituting unit derived from siloxane or its derivatives are bonded to each other.

Examples of the constituting unit having an aromatic group include a constituting unit having an aromatic group such as a phenyl group and a naphthyl group. Among them, a constituting unit derived from styrene or a derivative thereof is preferable.

Examples of the styrene or the derivative thereof include α-methylstyrene, 2-methylstyrene, 3-methylstyrene, 4-methylstyrene, 4-t-butylstyrene, 4-n-octylstyrene, 2,4,6-trimethylstyrene, 4-methoxystyrene, 4-t-butoxystyrene, 4-hydroxystyrene, 4-nitrostyrene, 3-nitrostyrene, 4-chlorostyrene, 4-fluorostyrene, 4-acetoxyvinylstyrene, 4-vinylbenzyl chloride, 1-vinylnaphthalene, 4-vinylbiphenyl, 1-vinyl-2-pyrrolidone, 9-vinylanthracene, and vinyl pyridine.

The (α-substituted) acrylic acid means one or both of an acrylic acid and ones in which a hydrogen atom bonded to an α-position carbon atom in the acrylic acid is substituted with a substituent. Examples of the substituents include an alkyl group having 1 to 5 carbon atoms.

Examples of the (α-substituted) acrylic acid include an acrylic acid and a methacrylic acid.

(α-Substituted) acrylic ester means one or both of acrylic ester and ones in which a hydrogen atom bonded to an α-position carbon atom in the acrylic ester is substituted with a substituent. Examples of the substituents include an alkyl group having 1 to 5 carbon atoms.

Examples of the (α-substituted) acrylic ester include acrylic ester such as methyl acrylate, ethyl acrylate, propyl acrylate, n-butyl acrylate, t-butyl acrylate, cyclohexyl acrylate, octyl acrylate, nonyl acrylate, hydroxyethyl acrylate, hydroxypropyl acrylate, benzyl acrylate, anthracene acrylate, glycidyl acrylate, 3,4-epoxycyclohexylmethane acrylate, and propyl trimethoxysilane acrylate; and methacrylic ester such as methyl methacrylate, ethyl methacrylate, propyl methacrylate, n-butyl methacrylate, t-butyl methacrylate, cyclohexyl methacrylate, octyl methacrylate, nonyl methacrylate, hydroxyethyl methacrylate, hydroxypropyl methacrylate, benzyl methacrylate, anthracene methacrylate, glycidyl methacrylate, 3,4-epoxycyclohexylmethane methacrylate, and propyl trimethoxysilane methacrylate.

Among them, methyl acrylate, ethyl acrylate, t-butyl acrylate, methyl methacrylate, ethyl methacrylate, and t-butyl methacrylate are preferable.

Examples of the siloxane or its derivatives include dimethyl siloxane, diethyl siloxane, diphenyl siloxane, and methyl phenyl siloxane.

Examples of the alkylene oxide include ethylene oxide, propylene oxide, isopropylene oxide, and butylene oxide.

As the constituting unit having a silsesquioxane structure, a constituting unit having a cage type silsesquioxane structure is preferable. As a monomer providing the constituting unit having the cage type silsesquioxane structure, a compound having the cage type silsesquioxane structure and a polymerizable group is exemplified.

Among them, as the block copolymer, a block copolymer including the block of the constituting unit having an aromatic group and the block of the constituting unit derived from an (α-substituted) acrylic acid or (α-substituted) acrylic ester is preferable. Among them, it is further preferable to include the block of the constituting unit derived from styrene, and (α-substituted) acrylic acid or a block of a constituting unit derived from (α-substituted) acrylic ester. In the block copolymer, the (α-substituted) acrylic acid or the block of the constituting unit derived from (α-substituted) acrylic ester is the hydrophilic block, and the block of the constituting unit derived from styrene is the hydrophobic block. Further, in the block copolymer, a polymer (p1) constituting the hydrophilic block is an (α-substituted) acrylic acid polymer or an (α-substituted) acrylic ester polymer.

In a case of obtaining a cylindrical phase-separated structure oriented in the direction perpendicular to the substrate surface, a mass ratio of the constituting unit having an aromatic group to the constituting unit derived from the (α-substituted) acrylic acid or the (α-substituted) acrylic ester is preferably in a range of 60:40 to 90:10, and is further preferably in a range of 60:40 to 80:20.

In addition, in a case of obtaining a lamellar phase-separated structure oriented in the direction perpendicular to the substrate surface, the mass ratio of the constituting unit having an aromatic group to the constituting unit derived from the (α-substituted) acrylic acid or the (α-substituted) acrylic ester is preferably in a range of 35:65 to 60:40, and is further preferably in a range of 40:60 to 60:40.

Specific examples of the block copolymer include a block copolymer having a block of the constituting unit derived from styrene and a block of a constituting unit derived from acrylic acid, a block copolymer having a block of a constituting unit derived from styrene and a block of the constituting unit derived from methyl acrylate, a block copolymer having a block of a constituting unit derived from styrene and the block of a constituting unit derived from ethyl acrylate, a block copolymer having a block of a constituting unit derived from styrene and a block of a constituting unit derived from t-butyl acrylate, a block copolymer having a block of the constituting unit derived from styrene and a block of the constituting unit derived from a methacrylic acid, a block copolymer having a block of the constituting unit derived from styrene and a block of the constituting unit derived from methyl methacrylate, a block copolymer having a block of the constituting unit derived from styrene and a block of a constituting unit derived from ethyl methacrylate, a block copolymer having a block of the constituting unit derived from styrene and a block of a constituting unit derived from t-butyl methacrylate, a block copolymer having a block of a cage type silsesquioxane (POSS) structure containing constituting unit and a block of a constituting unit derived from an acrylic acid, and a block copolymer having a block of the cage type silsesquioxane (POSS) structure containing constituting unit and a block of a constituting unit derived from methyl acrylate.

Note that, in the above-described block copolymers, the polymer (p1) is a poly(acrylic acid), poly(methyl acrylate), poly(ethyl acrylate), poly(t-butyl acrylate), a poly(methacrylic acid), poly(methyl methacrylate), poly(ethyl methacrylate), poly(t-butyl methacrylate), a poly(acrylic acid), and poly(methyl acrylate), respectively.

In the embodiment, particularly, it is preferable to use the block copolymer (PS-PMMA block copolymer) the block of the constituting unit derived from styrene (PS) and the block of the constituting unit derived from methyl methacrylate (PMMA).

The number average molecular weight (Mn) of the block copolymer (polystyrene conversion standard by gel permeation chromatography) is preferably equal to or greater than 6000, is further preferably in a range of 8000 to 200000, and is still further preferably in a range of 10000 to 160000.

The dispersity (Mw/Mn) of the block copolymer is preferably in a range of 1.0 to 3.0, is further preferably in a range of 1.0 to 1.5, and is still further preferably in a range of 1.0 to 1.3. Note that, “Mw” represents mass average molecular weight.

In the embodiment, the block copolymer may be used alone or two or more kinds thereof may be used in combination.

In the resin composition for forming a phase-separated structure of the embodiment, the content of the block copolymer may be adjusted depending on a thickness of a layer containing a block copolymer to be formed.

<Solvent Component (S)>

The resin composition for forming a phase-separated structure in the embodiment can be prepared by dissolving the block copolymer in a solvent component (S).

In the embodiment, the solvent component (S) contains an organic solvent (S1) having a boiling point of 200° C. or higher. The boiling point of the organic solvent (S1) is not particularly limited as long as it is 200° C. or higher, and is preferably 210° C. or higher, and is further preferably 220° C. or higher.

An upper limit value of the boiling point of the organic solvent (S1) is not particularly limited, but is preferably 300° C. or lower, is further preferably 280° C. or lower, and is still further preferably 250° C. or lower from the viewpoint of annealing treatment temperature or the like.

As the organic solvent (S1), any organic solvent having a boiling point of 200° C. or higher can be appropriately selected and used among known organic solvents for a film composition containing a resin as a main component.

Examples of the organic solvent (S1) include imidazolidinones such as 1,3-dimethyl-2-imidazolidinone (DMI); lactones such as α-methyl-γ-butyrolactone and γ-butyrolactone; polyhydric alcohols such as diethylene glycol and dipropylene glycol; a compound having an ester bond such as butyl diglycol diacetate, ethyl diglycol acetate, dipropylene glycol methyl ether acetate, and butylene glycol diacetate; derivatives of the polyhydric alcohols such as ethylene glycol, diethylene glycol, propylene glycol, and dipropylene glycol, or polyhydric alcohols such as a compound having an ether bond such as monoalkyl ether or monophenyl ether in a compound having an ester bond such as ethylene glycol monoacetate, diethylene glycol monoacetate, propylene glycol monoacetate, and dipropylene glycol monoacetate [among them, propylene glycol 1-monophenyl ether (PhFG) and dipropylene glycol monobutyl ether (BFDG) are preferable]; and an aromatic organic solvent such as diphenyl ether, dibenzyl ether, butylphenyl ether, ethylbenzene, diethylbenzene, and pentylbenzene.

Among them, as the organic solvent (S1), derivatives such as lactones, imidazolidinones, and polyhydric alcohols are preferable. In addition, in the lactones, a γ-butyrolactone having a substituent is preferable, and as a preferable example, α-methyl-γ-butyrolactone is exemplified. In addition, among the imidazolidinones, those having an alkyl group as a substituent are preferable, and as a preferable example, 1,3-dimethyl-2-imidazolidinone (DMI) is exemplified. Further, among the derivatives of polyhydric alcohols, a derivative having an ether bond of propylene glycol is preferable, and a derivative having a monoalkyl ether or monophenyl ether of propylene glycol is further preferable. As a preferable example, propylene glycol 1-monophennyl ether (PhFG) and dipropylene glycol monobutyl ether (BFDG) are preferable can be exemplified.

The organic solvent (S1) may be used alone or two or more kinds thereof may be used in combination.

In addition, in the organic solvent (S1), an interaction distance Ra_{S1} between a Hansen solubility parameter thereof and a Hansen solubility parameter of a polymer (p1) constituting a hydrophilic block of a block copolymer is preferably equal to or less than 6.0 MPa^{0.5}. When Ra_{S1} is equal to or less than the above upper limit value, the affinity between the organic solvent (S1) and the hydrophilic block of the block copolymer is improved, and the number of defects is reduced when a pattern is formed from the phase-separated structure.

The range of Ra_{S1} is preferably in a range of 1.0 to 6.0 MPa^{0.5}, is further preferably in a range of 2.0 to 6.0 MPa^{0.5}, and is still further preferably in a range of 2.5 to 6.0 MPa^{0.5}.

The Hansen solubility parameter can be calculated from a predetermined parameter based on the solubility parameter described by Charles Hansen in “Hansen Solubility Parameters: A User's Handbook” written by Charles M. Hansen, and “The CRC Handbook and Solubility Parameters and Cohesion Parameters,” (1999) edited by CRC Press (2007) and Allan F. M. Barton (1999), and an aggregation property.

The Hansen solubility parameter is theoretically calculated as a numerical constant and is a useful tool for predicting the ability of a solvent material to dissolve a particular solute.

The Hansen solubility parameter can be used as a measure of the overall strength and selectivity of a material by combining experimentally and theoretically derived three Hansen solubility parameters (that is, δD, δP, and δH). A unit of the Hansen solubility parameter is denoted MPa^{0.5} or (J/cc)^{0.5}.
δD: Energy derived from dispersive force between molecules
δP: Energy derived from polar force between molecules
δH: Energy derived from hydrogen bonding force between molecules

These three parameters (that is, δD, δP, and δH) are plotted as coordinates relating to points in three dimensions known as a Hansen space.

Within this three-dimensional space (Hansen space), the closer the two kinds of molecules are, the more likely they are to dissolve each other. Within the Hansen space, in order to evaluate whether or not two kinds of molecules (molecules (1) and (2)) are close to each other, an interaction distance (Ra) between the Hansen solubility parameters is calculated. Ra is calculated by the following expression.

(Ra)²=4(δ_{d2}−δ_{d1})²+(δₚ₂−δₚ₁)²+(δₕ₂−δₕ₁)²

[In the above Expression, δ_{d1}, δₚ₁, and δₕ₁ respectively represent by δD, δP, and δH of the molecule (1). δ_{d2}, δₚ₂, and δₕ₂ respectively represent δD, δP, and δH of the molecule (2).]

That is, the interaction distance Ra_{S1} between the Hansen solubility parameter of the organic solvent (S1) and the Hansen solubility parameter of the polymer (p1) can be calculated by the following expression.

(Ra_{S1})²=4(δ_{dp1}−δ_{dS1})²+(δₚₚ₁−δ_{pS1})²+(δₕₚ₁−δ_{kS1})²

[In the above Expression, δ_{dS1}, δ_{pS1}, and δ_{hS1} respectively represent δD, δP, and δH of the organic solvent (S1). δ_{dp1}, δₚₚ₁, and δₕₚ₁ respectively represent δD, δP, and δH of the polymer (p1).]

The Hansen solubility parameters of the organic solvent (S1) and the polymer (p1) can be calculated based on “Molecular Modeling Pro” software, version 5.1.9 (ChemSW, FairfieldCA, www.chemsw.com), or Hansen Solubility of Dynacomp Software.

For example, in a case where the polymer (p1) is poly(methyl methacrylate), examples of the organic solvent (S1) in which Ra_{S1} is equal to or less than 6.0 MPa^{0.5} include DMI (Ra_{S1}: 3.0), PhFG (Ra_{S1}: 5.8), and BFDG (Ra_{S1}: 5.6).

In addition, in the organic solvent (S1), an interaction distance Ra_{S1p2} between the Hansen solubility parameter of the organic solvent and a Hansen solubility parameter of a polymer (p2) constituting the hydrophobic block of the block copolymer is preferably equal to or greater than 6.0 MPa^{0.5}. When the Ra_{S1p2} is equal to or greater than the above-described lower limit value, the phase-separation performance is improved. The Ra_{S1p2} is preferably in a range of 6.0 to 15.0 MPa^{0.5}, is further preferably in a range of 7.0 to 12.0 MPa^{0.5}, and is still further preferably in a range of 8.0 to 10.0 MPa^{0.5}.

In addition, in the organic solvent (S1), a surface tension is preferably in a range of 10 to 100 mN/m. When the surface tension is within the above range, the film uniformity at the time of coating with a block copolymer is improved. The surface tension of the organic solvent (S1) is preferably in a range of 15 to 80 mN/m, and is further preferably in a range of 20 to 50 mN/m.

Further, the solvent component (S) preferably contains a main solvent (Sm) other than the organic solvent (S1). When the solvent component (S) contains the main solvent (Sm), the wettability at the time of coating a support with the resin composition for forming a phase-separated structure is improved.

As the main solvent (Sm), any solvent may be used as long as it can dissolve the components to be used and make it into a homogeneous solution. From among those known as a solvent of a film composition whose main component is resin, any one other than the organic solvent (S1) can be used by appropriately selecting one or two or more kinds thereof.

Examples of the main solvent (Sm) include lactones such as γ-butyrolactone; ketones such as acetone, methyl ethyl ketone, cyclohexanone, methyl-n-pentyl ketone, methyl isopentyl ketone, and 2-heptanone; polyhydric alcohols such as ethylene glycol, diethylene glycol, propylene glycol, and dipropylene glycol; a compound having an ester bond such as ethylene glycol monoacetate, diethylene glycol monoacetate, propylene glycol monoacetate, or dipropylene glycol monoacetate; derivatives of the polyhydric alcohols or polyhydric alcohols such as a compound having an ether bond such as monoalkyl ether of monomethyl ether, monoethyl ether, monopropyl ether, and monobutyl ether, or monophenyl ether in a compound having an ester bond [among them, propylene glycol monomethyl ether acetate (PGMEA) and propylene glycol monomethyl ether (PGME) are preferable]; esters such as cyclic ethers such as dioxane, methyl lactate, ethyl lactate (EL), methyl acetate, ethyl acetate, butyl acetate, methyl pyruvate, ethyl pyruvate, methyl methoxypropionate, and ethyl ethoxypropionate; and an aromatic organic solvent such as anisole, ethyl benzyl ether, cresyl methyl ether, diphenyl ether, dibenzyl ether, phenetole, butyl phenyl ether, ethyl benzene, diethyl benzene, pentyl benzene, isopropyl benzene, toluene, xylene, cymene, and mesitylene.

These may be used alone or two or more kinds thereof may be used in combination.

Among them, propylene glycol monomethyl ether acetate (PGMEA), propylene glycol monomethyl ether (PGME), cyclohexanone, and ethyl lactate (EL) are preferable.

In addition, as the main solvent (Sm), a mixed solvent in which PGMEA and a polar solvent are mixed is also preferable. The compounding ratio (mass ratio) may be appropriately determined in consideration of compatibility between the PGMEA and the polar solvent, and is preferably in a range of 1:9 to 9:1, and is further preferably in a range of 2:8 to 8:2.

For example, in a case of blending the EL as a polar solvent, the mass ratio of PGMEA:EL is preferably in a range of 1:9 to 9:1, and is further preferably in a range of 2:8 to 8:2. In addition, in a case of blending the PGME as a polar solvent, the mass ratio of PGMEA:PGME is preferably in a range of 1:9 to 9:1, is further preferably in a range of 2:8 to 8:2, and is still further preferably in a range of 3:7 to 7:3. In addition, in a case where blending the PGME and cyclohexanone as a polar solvent, the mass ratio of PGMEA:(PGME+cyclohexanone) is preferably in a range of 1:9 to 9:1, is further preferably in a range of 2:8 to 8:2, and is still further preferably in a range of 3:7 to 7:3.

In addition to the above-described solvent, preferable examples of the main solvent (Sm) include a mixed solvent of PGMEA or EL and γ-butyrolactone, and a mixed solvent of the mixed solvent of the PGMEA and the polar solvent, and γ-butyrolactone are also preferable. In this case, as a mixing ratio, the mass ratio of the former to the latter is preferably in a range of 70:30 to 95:5.

In addition, regarding the main solvent (Sm), an interaction distance Ra_{Sm} between the Hansen solubility parameters of the main solvent (Sm) and a polymer (p1) constituting a hydrophilic block of the block copolymer is preferably larger than the interaction distance Ra_{S1} between the Hansen solubility parameters of the organic solvent (S1) and the polymer (p1). That is, the interaction distance Ra_{S1} is preferably smaller than the interaction distance Ra_{Sm}.

In a case where the solvent component (S) contains the main solvent (Sm), the proportion of the main solvent (Sm) in the solvent component (S) is preferably equal to or greater than 50% by mass with respect to the total mass (100% by mass) of the solvent component (S). The proportion of the main solvent (Sm) in the solvent component (S) is preferably in a range of 50% to 99% by mass, is further preferably in a range of 60% to 98% by mass, and is still further preferably in a range of 70% to 97% by mass with respect to the total mass (100% by mass) of the solvent component (S).

In addition, in a case where the solvent component (S) contains the main solvent (Sm), the blending ratio (mass ratio) of the main solvent (Sm) and the organic solvent (S1) in the solvent component (S) is preferably in a range of 99:1 to 50:50, is further preferably in a range of 98:2 to 60:40, and is still further preferably in a range of 97:3 to 70:30.

When the blending ratio of the main solvent (Sm) and the organic solvent (S1) is within the above range, the wettability at the time of coating a support with the resin composition for forming a phase-separated structure is improved, and defects at the time of forming a pattern are reduced, thereby improving lithography properties such as CDU.

The proportion of the solvent component (S) in the resin composition for forming a phase-separated structure is not particularly limited, and is appropriately set according to the coating film thickness at a coatable concentration. Generally, the solvent component (S) is used such that the solid content concentration is within the range of 0.2% to 70% by mass, and is preferably in a range of 0.2% to 50% by mass.

<Optional Component>

The resin composition for forming a phase-separated structure in the embodiment can appropriately contain, in addition to the above-described block copolymer and the solvent component (S), miscible additives such as an additional resin for improving the performance of an undercoating agent layer, a surfactant for improving coatability, a dissolution inhibitor, a plasticizer, a stabilizer, a colorant, an antihalation agent, a dye, a sensitizer, a base proliferator, and a basic compound, as necessary.

According to the above-described resin composition for forming a phase-separated structure in the embodiment, by using the solvent component (S) contains the organic solvent (S1) having a boiling point of 200° C. or higher, it is possible to form an excellent phase-separated structure. In addition, when forming a pattern from the phase-separated structure, it is possible to obtain a good pattern with fewer defects and improved lithography properties such as CDU. The reason for this is considered that when the solvent component (S) contains the organic solvent (S1), the affinity with the solvent component (S) and the hydrophilic block of the block copolymer is improved.

Further, when forming of the phase-separated structure, generally, an excellent phase-separated structure is formed in the vicinity of a central portion of an area which the resin composition for forming a phase-separated structure is applied, as the edge becomes closer, the phase-separated structure is less likely to be formed. However, according to the resin composition for forming a phase-separated structure in the embodiment, even in the vicinity of the edge of the area which the resin composition for forming a phase-separated structure is applied, it is possible to form an excellent phase-separated structure. For this reason, when forming a pattern from the phase-separated structure, it is possible to obtain an excellent pattern having fewer defects even in the edge of the area (corresponding to the “area which the resin composition for forming a phase-separated structure is applied”) in which the pattern is formed.

(Method of Producing Structure including Phase-Separated Structure)

According to the second aspect of the present invention, a method of producing a structure including a phase-separated structure includes a step (hereinafter, referred to as “Step (i)”) of applying the resin composition for forming a phase-separated structure according to the first aspect to a support to form a layer including a block copolymer, and a step (hereinafter, referred to as “Step (ii)”) of phase-separating the layer including the block copolymer.

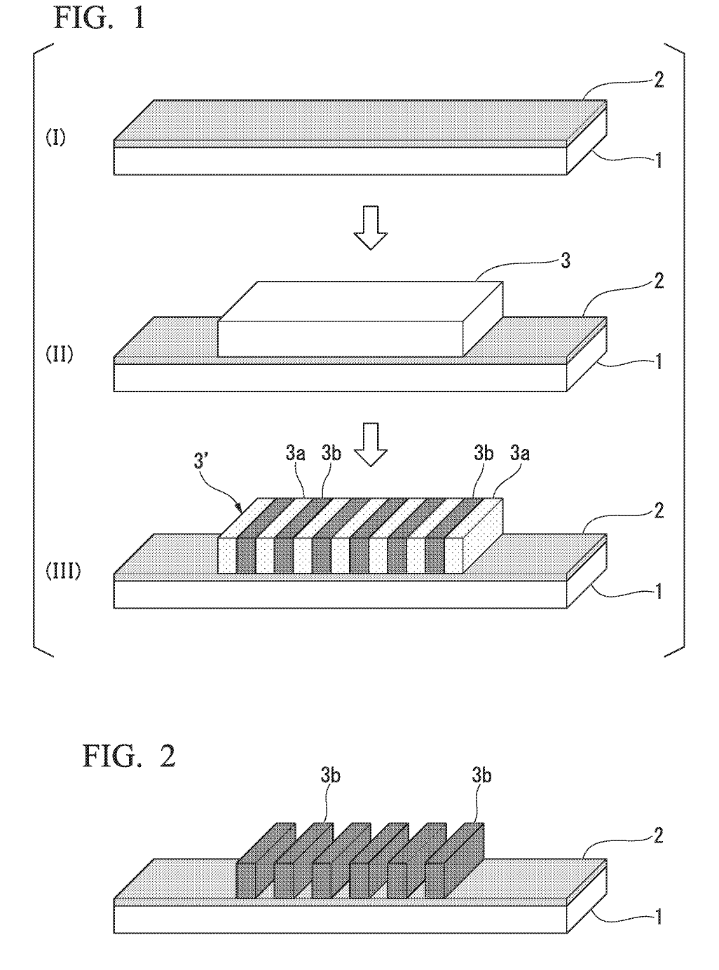

Hereinafter, the method of producing a structure including a phase-separated structure will be specifically described with reference to FIG. 1. Here, the present invention is not limited thereto.

FIG. 1 illustrates an exemplary embodiment of the method of producing a structure including a phase-separated structure.

First, as necessary, an undercoating agent is applied to a support to form an undercoating agent layer 2 (FIG. 1 (I)).

Then, the resin composition for forming a phase-separated structure is applied to the undercoating layer 2 to form a layer (BCP layer) 3 including a block copolymer (FIG. 1 (II); Step (i)).

Next, the BCP layer 3 is phase-separated into a phase 3a and a phase 3b by heating and annealing treatment (FIG. 1 (III); Step (ii)).

According to the producing method of the embodiment, that is, the producing method including Step (i) and Step (ii), a structure 3′ including a phase-separated structure is produced on the support 1 on which the undercoating agent layer 2 is formed.

[Step (i)]

In Step (i), the BCP layer 3 is formed on the support 1 by using the resin composition for forming a phase-separated structure.

The support is not particularly limited as long as the resin composition for forming a phase-separated structure can be applied to its surface.

Examples of the support include a substrate made of a metal such as silicon, copper, chromium, iron, and aluminum, a substrate made of an inorganic material such as glass, titanium oxide, silica, and mica, an acrylic plate, and a substrate made of an organic compound such as polystyrene, cellulose, cellulose acetate, and phenol resin.

The size and shape of the support are not particularly limited. The support does not necessarily have a smooth surface and the support of various materials and shapes can be selected appropriately. For example, various shapes such as a substrate having a curved surface, a flat plate having an uneven surface, a thin plate shape, and the like can be variously used.

On the surface of the support, an inorganic and/or an organic film may be provided. Examples of the inorganic film include an inorganic antireflection film (inorganic BARC). Examples of the organic film include an organic antireflection film (organic BARC).

Before forming the BCP layer 3 on the support 1, the surface of the support 1 may be cleaned. When the surface of the support 1 is cleaned, the support 1 can be more effectively coated with the resin composition for forming a phase-separated structure or the undercoating agent.

As a cleaning treatment, a conventionally known method can be used, and examples thereof include an oxygen plasma treatment, a hydrogen plasma treatment, an ozone oxidation treatment, an acid alkali treatment, and a chemical modification treatment. For example, the support is immersed in an acid solution such as a sulfuric acid/hydrogen peroxide solution, and then washed with water and dried. After that, the BCP layer 3 or the undercoating agent layer 2 is formed on the surface of the support.

It is preferable to neutralize the support 1 before forming the BCP layer 3 on the support 1.

A neutralization treatment is a treatment to modify the support surface to have affinity with any polymer constituting the block copolymer. By performing the neutralization treatment, it is possible to prevent only a phase of a specific polymer to come into contact with the support surface by the phase separation. For example, before forming the BCP layer 3, it is preferable to form an undercoating agent layer 2 on the surface of the support 1 in accordance with the type of the block copolymer to be used. With this, due to the phase separation of the BCP layer 3, it is easy to form a cylinder-like or lamellar phase-separated structure oriented perpendicularly to the surface of the support 1.

Specifically, the undercoating agent layer 2 is formed on the surface of the support 1 by using an undercoating agent having the affinity with any polymer constituting the block copolymer.

As the undercoating agent, a conventionally known resin composition used for forming a thin film can be appropriately selected and used in accordance with the type of the polymer constituting the block copolymer.

Examples of the undercoating agent include a composition containing a resin having all constituting units of each polymer constituting the block copolymer, and a composition containing a resin having constituting units with high affinity with each polymer constituting the block copolymer.

For example, in a case of using a block copolymer (PS-PMMA block copolymer) including a block of the constituting unit derived from styrene (PS) and a block of the constituting unit derived from methyl methacrylate (PMMA), as the undercoating agent, it is preferable to use a resin composition containing both PS and PMMA as a block or a compound or a composition containing both a portion having high affinity with an aromatic ring or the like and a portion having high affinity with a highly polar functional group or the like.

Examples of the resin composition containing both PS and PMMA as a block include a random copolymer of PS and PMMA, and an alternating polymer of PS and PMMA (a copolymer in which the respective monomers are alternately copolymerized).

Further, as a composition containing both a portion having the high affinity with PS and a portion having the high affinity with PMMA, for example, a resin composition obtained by polymerizing at least a monomer having an aromatic ring and a monomer having a highly polar substituent as a monomer can be exemplified. Examples of the monomer having an aromatic ring include a monomer having a group in which one hydrogen atom has been removed from an aromatic hydrocarbon ring, such as a phenyl group, a biphenyl group, a fluorenyl group, a naphthyl group, an anthryl group, and a phenanthryl group, or a monomer having a heteroaryl group in which a part of the carbon atoms constituting the ring of the aforementioned groups is substituted with a hetero atom such as an oxygen atom, a sulfur atom, and a nitrogen atom. Examples of the monomer having a highly polar substituent include a monomer having a hydroxyalkyl group in which a part of hydrogen atoms of a trimethoxysilyl group, a trichlorosilyl group, a carboxy group, a hydroxyl group, a cyano group, and an alkyl group is substituted with a fluorine atom.

Examples of other compounds containing both the portion with high affinity with PS and the portion with high affinity with PMMA include a compound containing both an aryl group such as phenethyltrichlorosilane and a highly polar substituent, and a compound containing both an alkyl group such as a silane compound and a highly polar substituent.

Further, examples of the undercoating agent include a photosensitive resin composition such as a heat-polymerizable resin composition, a positive resist composition, and a negative resist composition.

These undercoating agent layers can be formed by using a conventional method.

A method of forming the undercoating agent layer 2 by applying the undercoating agent to the support 1 is not particularly limited, and the undercoating agent layer 2 can be formed by using a conventionally known method.

For example, the undercoating agent layer 2 can be formed by forming a coated film obtained by coating the support 1 with undercoating agent using a spin coater and a spinner through a conventionally known method, and then drying the coated film.

A method of drying the coated film may be any method as long as the solvent contained in the undercoating agent can be volatilized, and for example, a method of baking the film is exemplified. At this time, a baking temperature is preferably in a range of 80° C. to 300° C., is further preferably in a range of 180° C. to 270° C., and is still further preferably in a range of 220° C. to 250° C. The baking time is preferably in a range of 30 to 500 seconds, and is further preferably in a range of 60 to 400 seconds.

The thickness of the undercoating agent layer 2 after drying the coated film is preferably in a range of 10 to 100 nm, and is further preferably in a range of 40 to 90 nm.

Then, the BCP layer 3 is formed on the undercoating agent layer 2 by using the resin composition for forming a phase-separated structure.

The method of forming the BCP layer 3 on the undercoating agent layer 2 is not particularly limited, and examples thereof include a method of forming a coated film by coating the undercoating agent layer 2 with the resin composition for forming a phase-separated structure using a spin coater and a spinner through a conventionally known method, and then drying the coated film.

The method of drying the coated film of the resin composition for forming a phase-separated structure may be any method as long as an organic solvent component which is contained in the resin composition for forming a phase-separated structure can be volatilized, and for example, a shake-off drying method, and a baking method are exemplified.

The thickness of the BCP layer 3 may be a thickness sufficient for the phase separation to occur, and is preferably in a range of 10 to 100 nm, and is further preferably in a range of 30 to 80 nm in consideration of the type of the support 1, the periodic size of the structure of the phase-separated structure to be formed, or the uniformity of a nano-structure.

For example, in a case where the support 1 is a Si substrate or a SiO₂ substrate, the thickness of the BCP layer 3 is preferably in a range of 20 to 100 nm, and is further preferably in a range of 30 to 80 nm.

In a case where the support 1 is a Cu substrate, the thickness of the BCP layer 3 is preferably in a range of 10 to 100 nm, and is further preferably in a range of 30 to 80 nm.

[Step (ii)]

In Step (ii), the BCP layer 3 formed on the support 1 is phase-separated.

By heating and annealing the support 1 after Step (i), a phase-separated structure is formed such that at least a part of the surface of the support 1 is exposed by selective removal of the block copolymer. That is, a structure 3′ including a phase-separated structure which is phase-separated into a phase 3a and a phase 3b is formed on the support 1.

As the temperature condition of the annealing treatment, it is preferable that the temperature is equal to or higher than a glass transition temperature of the block copolymer to be used, and is lower than a thermal decomposition temperature. For example, in a case where the block copolymer is a PS-PMMA block copolymer (number average molecular weight in a range of 6000 to 200000), as the temperature condition of the annealing treatment, the temperature is preferably in a range of 100° C. to 400° C., is further preferably in a range of 120° C. to 350° C., and is particularly preferably in a range of 150° C. to 300° C. The heating time is preferably in a range of 30 to 3600 seconds, and is further preferably in a range of 120 to 600 seconds.

The annealing treatment is preferably performed in a gas having low reactivity such as nitrogen.

According to the method of producing a structure including a phase-separated structure of the embodiment described above, by using the resin composition for forming a phase-separated structure of the embodiment described above, it is possible to obtain a structure including a phase-separated structure which is capable of forming an excellent pattern with few defects and improved lithography properties such as CDU.

[Optional Steps]

The method of producing a structure including a phase-separated structure according to the present invention is not limited to the above-described embodiment, and may have steps (optional steps) other than Steps (i) to (ii).

Examples of the optional steps include a step (hereinafter, referred to “Step (iii)”) of selectively removing a phase formed of at least one kind of block among the plurality of kinds of blocks constituting the block copolymer in the BCP layer 3, and a guide pattern forming step.

Regarding Step (iii)

In Step (iii), the phases (phase 3a, phase 3b) formed of at least one kind of block among the plurality of kinds of blocks constituting the block copolymer in the BCP layer 3 formed on the undercoating agent layer 2 are selectively removed. As a result, a fine pattern (high molecular nano-structure) is formed.

Examples of a method of selectively removing the phase formed of the block include a method of performing an oxygen plasma treatment on the BCP layer and a method of performing a hydrogen plasma treatment.

In the following description, among the blocks constituting the block copolymer, a block that is not selectively removed is referred to as a P_{A} block, and a block that is selectively removed is referred to as a P_{B} block. For example, after phase-separating a layer including a PS-PMMA block copolymer, the phase formed of PMMA is selectively removed by performing an oxygen plasma treatment, a hydrogen plasma treatment, or the like on the phase-separated layer. In this case, a PS part is the P_{A} block and a PMMA part is the P_{B} block.

FIG. 2 illustrates an exemplary embodiment of Step (iii).

In the exemplary embodiment as illustrated in FIG. 2, the phase 3a is selectively removed by performing the oxygen plasma treatment on the structure 3′ prepared on the support 1 in Step (ii), and a pattern (high molecular nano-structure) formed of the separated phase 3b is formed. In this case, the phase 3b is a phase formed of the P_{A} block and the phase 3a is a phase formed of the P_{B} block.

As described above, the support 1 with the pattern formed by the phase separation of the BCP layer 3 can be used as it is, but it is also possible to change the shape the pattern (high molecular nano-structure) of the support 1 by further heating.

As the temperature condition for heating, equal to or higher than a glass transition temperature of the block copolymer to be used, and is preferably lower than a thermal decomposition temperature. In addition, the heating is preferably performed in a gas having low reactivity such as nitrogen.

Regarding Guide Pattern Forming Step

The method of producing a structure including a phase-separated structure according to the present embodiment may include a step (guide pattern forming step) of providing a guide pattern on a support or an undercoating agent layer. With this, it possible to control an array structure of the phase-separated structure.

For example, even with the block copolymer in which a random fingerprint phase-separated structure is formed in a case where a guide pattern is not provided, when a groove structure of the resist film on the surface of the undercoating agent layer is provided, it is possible to obtain a phase-separated structure oriented on the groove. With this principle, the guide pattern may be provided on the undercoating agent layer 2. In addition, when the surface of the guide pattern has the affinity with any of the polymers constituting the block copolymer, it is likely to form a cylinder-like or lamellar phase-separated structure oriented in the direction perpendicular to the support surface.

The guide pattern can be formed, for example, by using a resist composition.

As for the resist composition for forming the guide pattern, among the resist composition generally used for forming the resist pattern and its modification, those having affinity with any one of polymers constituting the block copolymer can be appropriately selected and used. The resist composition may be any one of a positive resist composition which forms a positive pattern in which a resist film exposed portion is dissolved and removed, and a negative resist composition which forms a negative pattern in which a resist film unexposed portion is dissolved and removed, and is preferably the negative resist composition. The negative resist composition contains, for example, an acid generator component and a base component in which the solubility of a developer containing an organic solvent is reduced by the action of an acid, and a resist composition in which the base component contains a resin component having a constituting unit that decomposes by the action of an acid to increase the polarity is preferable.

After the resin composition for forming a phase-separated structure is poured onto the undercoating agent layer on which the guide pattern is formed, the annealing treatment is performed to cause the phase separation. Therefore, as the resist composition for forming a guide pattern, resist composition capable to form a resist film excellent in the solvent resistance and heat resistance is preferable.

In addition, a guide pattern may be formed by forming a spin-on-carbon (SOC) layer, a silicon hard mask layer, or the like on the support, and etching these layers. For example, a resist pattern by a resist composition is formed on the SOC layer or the silicon hard mask layer formed on the support, and the resist pattern is used as a mask so as to form a guide pattern by etching the SOC layer or the silicon hard mask layer with fluorine-based gas or oxygen-based gas.

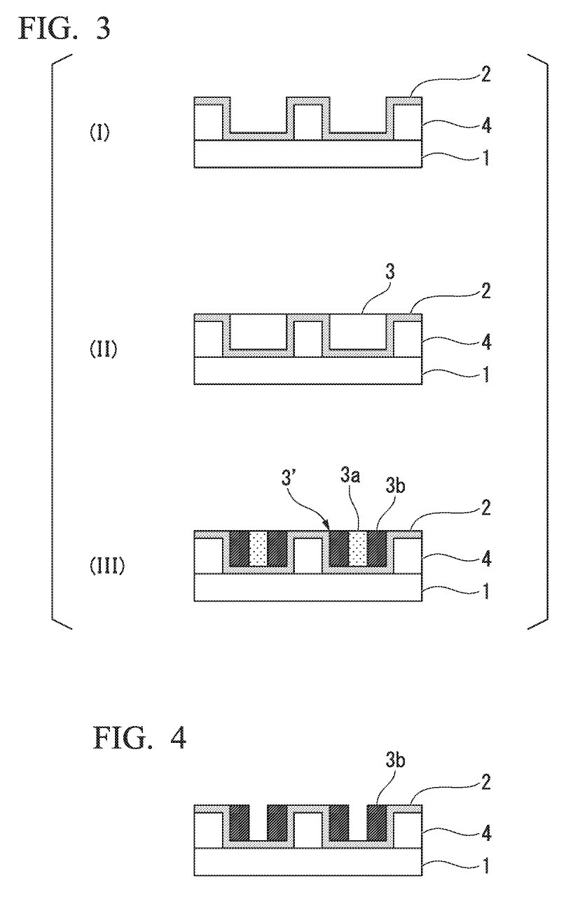

FIG. 3 illustrates an exemplary embodiment of producing a structure including a phase-separated structure using the guide pattern of the SOC layer, the silicon hard mask layer, or the like.

In the exemplary embodiment as illustrated in FIG. 3, the undercoating agent layer 2 is formed by applying the undercoating agent to the support 1, on which a recess formed by a guide pattern 4 (FIG. 3 (I)). Next, the BCP layer 3 is formed by applying the resin composition for forming a phase-separated structure to the undercoating agent layer 2 so as to fill the recess formed by the guide pattern 4 (FIG. 3 (II)). The above step corresponds to Step (I) described above, and it may be performed in the same way as the example described in the above-described “[Step (i)]” except that the support 1 having the guide pattern 4 is used.

Next, the support 1 on which the BCP layer 3 is formed is heated and annealed to phase-separate the BCP layer 3 into the phase 3a and the phase 3b (FIG. 3 (III)). The above step corresponds to Step (ii) described above and may be performed in the same way as the example described in the above-described “[Step (ii)]”.

In addition, FIG. 4 illustrates an exemplary embodiment in which the phase 3a is selectively removed in the structure including a phase-separated structure produced by using the guide pattern as described above. The selective removal of the phase 3a corresponds to Step (iii) described above and may be performed in the same manner as the example described in “Regarding Step (iii)”. With the selective removal of the phase 3a, a pattern is formed on the support 1. By controlling the shape of the guide pattern 4, patterns of various shapes such as a hole pattern and a line pattern can be formed on the support 1.

### EXAMPLES

Hereinafter, the present invention will be described in more detail with reference to Examples, but the present invention is not limited by these Examples.

In Examples, a compound represented by Chemical Formula (1) is expressed as “Compound (1)”, and the same is true for compounds represented by other chemical formulae.

### Examples 1 to 3, Comparative Example 1

<Preparation of Resin Composition for Forming Phase-Separated Structure>

The respective components shown in Table 1 were mixed and dissolved so as to prepare a resin composition for forming a phase-separated structure (Solid content concentration: 1.2% by mass) of in each Example.

TABLE 1

| | | Solvent component (S) | |
|---|---|---|---|
| Resin composition for forming | Block | Main | Organic |
| phase-separated structure | copolymer | solvent (Sm) | solvent (S1) |
| Example 1 | BCP-(1) | Sm-(1) | S1-(1) |
| | | (80) | (20) |
| Example 2 | BCP-(1) | Sm-(1) | S1-(2) |
| | | (95) | (5) |
| Example 3 | BCP-(1) | Sm-(1) | S1-(3) |
| | | (95) | (5) |
| Comparative Example 1 | BCP-(1) | Sm-(1) | — |
| | | (100) | |

In Table 1, each abbreviation has the following meaning. The numerical values in parentheses are the blending amount (parts by mass) based on 100 parts by mass of the solvent component (S).

BCP-(1): Block copolymer of polystyrene (PS block) and polymethyl methacrylate (PMMA block) [Mn: PS of 82 k, PMMA of 29 k, 111 k in total; Composition ratio (mass ratio) of PS/PMMA 74/26; Dispersity of 1.02]

Sm-(1): Propylene glycol monomethyl ether acetate (PGMEA)

S1-(1): 1,3-dimethyl-2-imidazolidinone (DMI)

S1-(2): Propylene glycol 1-monophenyl ether (PhFG)

S1-(3): Dipropylene glycol monobutyl ether (BFDG)

The physical properties of the main solvent (Sm) and the organic solvent (S1) which are used in the preparation of the resin composition for forming a phase-separated structure are shown in Table 2.

TABLE 2

| | Ra_{PS} | Ra_{PMMA} | Boiling point | Surface tension |
|---|---|---|---|---|
| Solvent | (MPa^{0.5}) | (MPa^{0.5}) | (° C.) | (mN/m) |
| S1-(1) | 9.2 | 3.0 | 220 | 41.0 |
| S1-(2) | 8.9 | 5.8 | 242.7 | 37.8 |
| S1-(3) | 9.3 | 5.6 | 230.6 | 23.7 |
| Sm-(1) | 9.1 | 6.1 | 146 | 26.7 |

In Table 2, each abbreviation has the following meaning.

Ra_{PS}: Interaction distance Ra between Hansen solubility parameter of solvent and Hansen solubility parameter of polystyrene.

Ra_{PMMA}: Interaction distance Ra between Hansen solubility parameter of solvent and Hansen solubility parameter of polymethyl methacrylate.

<Production of Structure including Phase-Separated Structure>

[Formation of Guide Pattern]

On a 12-inch silicon wafer, a spin-on-carbon (SOC) layer with a film thickness of 100 nm and a silicon hard mask film with a film thickness of 10 nm were formed in this order. Then, a resist film was formed on the silicon hard mask film. The resist film was subjected to an exposure treatment with ArF light of 193 nm using an ArF exposure apparatus and then developed so as to form a desired resist pattern.

Next, the resist film having the resist pattern was used as a mask, and then the silicon hard mask film was etched with fluorine gas. As a result, the pattern was transferred to the silicon hard mask film.

Next, the silicon hard mask film to which the pattern was transferred was used as a mask, the SOC layer under the silicon hard mask film was etched with oxygen-based gas to transfer the pattern, and thereby a guide pattern was formed. The formed guide pattern was a trench pattern with a pitch of 180 nm, and 20 kinds of guide patterns with a trench width in a range of 55 to 65 nm, which were different from each other by 0.5 nm increments, were obtained. The guide pattern of each trench width has a pattern area of 5 μm×8 μm.

[Step (i)]

A silicon wafer on which the guide pattern was formed as described above was coated with the following undercoating agent by spin coating (rotational speed: 1500 rpm, 30 seconds), and then the coated silicon wafer was baked in atmosphere at 90° C. for one minute, and dried so as to form an undercoating agent layer having a thickness of 100 nm.

As an undercoating agent, a terminally modified polystyrene resin PGMEA solution (resin concentration 3% by mass) was used.

Then, the undercoating agent layer was rinsed with PGMEA for 60 seconds to remove the polymer such as unreacted areas. After that, baking was performed at 250° C. for 60 seconds. After baking, the film thickness of the undercoating agent layer formed on the wafer was 2 nm.

Next, the resin compositions for forming a phase-separated structure (Solid content concentration: 1.2% by mass) in Examples were spin-coated (rotation speed: 1500 rpm, 30 seconds) so as to cover the undercoating agent layer formed on the wafer, the coated film were shake-off dried, and thereby a PS-PMMA block copolymer layer having a thickness of 30 nm was formed.

[Step (ii)]

Next, the annealing treatment was performed by heating at 250° C. for 300 seconds in a nitrogen stream to phase-separate the PS-PMMA block copolymer layer into a phase formed of PS and a phase formed of PMMA so as to form a structure including the phase-separated structure.

[Step (iii)]

The wafer on which the phase-separated structure is prepared was subjected to an oxygen plasma treatment so as to selectively remove a phase formed of PMMA.

<Process Window>

A total of 20 shots of hole patterns were formed by the above-described method with 20 kinds of guide patterns with a trench width in a range of 55 to 65 nm, which were different from each other by 0.5 nm increments. The 20 shots of hole patterns were observed, and the hole formed for each pattern was evaluated. The number of patterns in which 90% or more holes can be formed without defects was counted and set as the value of the process window.

The term “defect” as used herein refers to a state in which there is no hole to be present or a state in which a plurality of holes to be separated are connected.

<Evaluation of Number of Defects>

In the above-described “<Evaluation of process window>”, among the patterns evaluated that 90% or more holes were formed without defects, the number of defects in the shot with the smallest number of defects was counted and set as the value of the number of defects.

<Evaluation of In-Plane Uniformity (CDU) of Pattern Dimension>

A CH pattern was observed from the sky with a scanning electron microscope SEM (SU 8000, manufactured by Hitachi High-Technologies Corporation), and a hole diameter (nm) of 100 holes in the CH pattern was measured.

A value of three times (3σ) standard deviation (σ) calculated from the measurement result was obtained. The results are shown in Table 3 as “CDU (nm)”.

3σ obtained in this way means that means that the smaller the value, the higher the dimension (CD) uniformity of the hole formed in the resist film.

<Evaluation of Completeness of Pattern Periphery>

In the above-described “<evaluation of process window>”, among the patterns evaluated that 90% or more of holes can be formed without defects, regarding the shots having the smallest number of defects, the holes formed in a row in the outermost of the pattern area was observed. Then, regarding the holes in a row on the outside, the number of defects was counted and evaluated as the completeness of pattern periphery. A sample in which defects were not observed was evaluated as A, a sample in which one or two defects were observed was evaluated as B, and a sample in which three or more defects were observed was evaluated as C.

TABLE 3

| | Process | Number of | CDU | Completeness of |
|---|---|---|---|---|
| | window | defects | (nm) | pattern periphery |
| Example 1 | 3 | 0 | 3.41 | A |
| Example 2 | 4 | 0 | 3.17 | A |
| Example 3 | 6 | 0 | 3.14 | A |
| Comparative Example 1 | 3 | 5 | 3.54 | C |

From the results as shown in Table 3, in the resin compositions for forming a phase-separated structure of Examples 1 to 3 to which the present invention is applied, it was confirmed that the number of defects was small and the value of CDU was also excellent as compared with Comparative Example. In addition, it was confirmed that the completeness of pattern periphery was also high.

### EXPLANATION OF REFERENCES

1 . . . support, 2 . . . undercoating agent layer, 3 . . . BCP layer, 3′ . . . structure, 3a . . . phase, 3b . . . phase, 4 . . . guide pattern

What is claimed is:

1. A resin composition for forming a phase-separated structure, comprising:
a block copolymer in which a hydrophobic block and a hydrophilic block are bonded to each other; and
a solvent component (S) containing an organic solvent (S1) having a boiling point of 200° C. or higher.

2. The resin composition for forming a phase-separated structure according to claim 1, wherein an interaction distance Ra_{S1} between a Hansen solubility parameter of the organic solvent (S1) and a Hansen solubility parameter of a polymer (p1) constituting the hydrophilic block is equal to or less than 6.0 MPa^{0.5}.

3. The resin composition for forming a phase-separated structure according to claim 1, wherein the solvent component (S) contains the organic solvent (S1) and solvents other than the organic solvent (S1) as a main solvent (Sm), and
wherein a proportion of the main solvent (Sm) in the solvent component (S) is equal to or greater than 50% by mass with respect to a total mass of the solvent component (S).

4. The resin composition for forming a phase-separated structure according to claim 3, wherein the interaction distance Ra_{S1} is smaller than an interaction distance Ra_{Sm} between a Hansen solubility parameter of the main solvent (Sm) and of a Hansen solubility parameter of the polymer (p1).

5. The resin composition for forming a phase-separated structure according to claim 1, wherein the hydrophilic block is a block of a constituting unit derived from (α-substituted) acrylic ester.

6. The resin composition for forming a phase-separated structure according to claim 5, wherein the hydrophilic block is polymethyl methacrylate.

7. The resin composition for forming a phase-separated structure according to claim 1, wherein the hydrophobic block is a block of a constituting unit having an aromatic group.

8. A method of producing a structure including a phase-separated structure, the method comprising:
applying the resin composition for forming a phase-separated structure according to claim 1 to a support to form a layer including the block copolymer; and
phase-separating the layer including the block copolymer.
